(19) United States
(12) Patent Application Publication
(10) Pub. No.: US 2026/0198191 A1
(43) Pub. Date: Jul. 9, 2026

(54) DISPLAY DEVICE AND ELECTRONIC DEVICE INCLUDING THE SAME

(71) Applicant: Samsung Display Co., Ltd., Yongin-si (KR)

(72) Inventors: HYOUNGHAK KIM, Yongin-si (KR); TAEJONG EOM, Yongin-si (KR)

(21) Appl. No.: 19/289,999

(22) Filed: Aug. 4, 2025

(30) Foreign Application Priority Data
Jan. 3, 2025 (KR) 10-2025-0000849

(51) Int. Cl. H10K 59/131

(52) U.S. Cl. CPC H10K 59/131

(57) ABSTRACT

A display device includes a substrate including a display area, a peripheral area outside the display area, and a pad area in the peripheral area, a data line in the display area, a fan-out interconnection having one side electrically connected to the data line and another side extending to the pad area, a power interconnection extending in a direction different from that of the fan-out interconnection, and a connecting element positioned at a same layer as the power interconnection and connecting the one side of the fan-out interconnection to the data line, wherein the fan-out interconnection includes a protrusion that protrudes in a direction perpendicular to a longitudinal direction of the fan-out interconnection between the connecting element and the power interconnection.

### CROSS-REFERENCE TO RELATED APPLICATION

The present application claims priority to and the benefit of Korean Patent Application No. 10-2025-0000849, filed on Jan. 3, 2025, in the Korean Intellectual Property Office, the entire disclosure of which is incorporated herein by reference.

### BACKGROUND

### 1. Field

Aspects of the present disclosure relate to a display device and an electronic device including the same.

### 2. Description of the Related Art

Recently, various lightweight and compact flat panel display devices are being developed. Flat panel display devices include liquid crystal displays (LCDs), field emission displays (FEDs), plasma display panels (PDPs), and organic light-emitting displays (OLEDs), for example.

Among flat panel display devices, organic light-emitting display devices (OLEDs) display images by using organic light-emitting diodes (OLEDs), which emit light through the recombination of electrons and holes. Such organic light-emitting display devices are receiving attention as next-generation displays because they may be driven with low power consumption while having fast response speed.

The above information disclosed in this Background section is only for enhancement of understanding of the background of the invention and therefore it may contain information that does not form.

### SUMMARY

With the increasing integration of display devices, when a power interconnection and a connecting element, which are adjacent to each other and may be positioned at the same layer on a substrate, are arranged, an unetched residual film may remain between the power interconnection and the connecting element, causing current to flow along the residual film, thereby causing the power interconnection and the connecting element to short circuit with each other.

Accordingly, aspects of some embodiments of the present disclosure are directed to a display with improved stability by preventing or substantially reducing incidents of short circuits between a power interconnection and a connecting element, and an electronic device including the same.

However, the technical problems to be solved by the present disclosure are not limited to the problems described above, and other problems not described may be clearly understood by those skilled in the art from the description of the present disclosure described below.

According to some embodiments of the present disclosure, there is provided a display device including: a substrate including a display area, a peripheral area outside the display area, and a pad area in the peripheral area; a data line in the display area; a fan-out interconnection having one side electrically connected to the data line and another side extending to the pad area; a power interconnection extending in a direction different from that of the fan-out interconnection; and a connecting element positioned at a same layer as the power interconnection and connecting the one side of the fan-out interconnection to the data line, wherein the fan-out interconnection includes a protrusion that protrudes in a direction perpendicular to a longitudinal direction of the fan-out interconnection between the connecting element and the power interconnection.

In some embodiments, the protrusion is arranged continuously with an overlapping area of the connecting element and the fan-out interconnection.

In some embodiments, a width of the protrusion along the longitudinal direction of the fan-out interconnection is 3 μm to 10 μm.

In some embodiments, the protrusion protrudes from opposite sides of the fan-out interconnection.

In some embodiments, the protrusion is offset from an overlapping area of the connecting element and the fan-out interconnection.

In some embodiments, the protrusion of the fan-out interconnection includes a plurality of protrusions, and the plurality of protrusions are offset from each other along the longitudinal direction of the fan-out interconnection.

In some embodiments, rein the protrusion of the fan-out interconnection includes a plurality of protrusions, and the protrusions include at least one first protrusion and at least one second protrusion extending in opposite directions.

In some embodiments, the fan-out interconnection includes a zigzag pattern between the connecting element and the power interconnection.

In some embodiments, one end of the fan-out interconnection is electrically connected to a driving circuit part.

In some embodiments, the fan-out interconnection extends in a direction parallel to a bending direction in a bending region.

According to some embodiments of the present disclosure, there is provided a display device including: a substrate including a display area, a peripheral area outside the display area, and a pad area in the peripheral area; a thin film transistor on the substrate; a light-emitting element electrically connected to the thin film transistor; a data line through which a data signal is applied to the thin film transistor; a fan-out interconnection having one side electrically connected to the data line and another side extending to the pad area; and a connecting element for connecting the one side of the fan-out interconnection to the data line, wherein the fan-out interconnection includes a protrusion that protrudes in a direction perpendicular to a longitudinal direction of the fan-out interconnection outside an overlapping area of the connecting element and the fan-out interconnection.

In some embodiments, the display device further includes: an upper electrode of a capacitor or a lower electrode of the capacitor formed in a same layer as the data line.

In some embodiments, the data line and the fan-out interconnection are at different layers.

In some embodiments, the display device further includes: a power interconnection extending in a direction different from that of the fan-out interconnection, wherein the power interconnection is positioned at a same layer as the connecting element.

In some embodiments, the protrusion is between the connecting element and the power interconnection.

In some embodiments, the protrusion is arranged continuously with an overlapping area of the connecting element and the fan-out interconnection.

In some embodiments, a width of the protrusion along the longitudinal direction of the fan-out interconnection is 3 μm to 10 μm.

In some embodiments, the protrusion is offset from an overlapping area of the connecting element and the fan-out interconnection.

In some embodiments, the protrusion of the fan-out interconnection includes a plurality of protrusions, and the plurality of protrusions are offset from each other along the longitudinal direction of the fan-out interconnection.

In some embodiments, the fan-out interconnection includes a plurality of fan-out interconnections and the protrusion includes a plurality of protrusions, and a protrusion of one of the fan-out interconnections is arranged to be alternately staggered with respect to a protrusion of another one of the fan-out interconnections which is adjacent to the one of the fan-out interconnections.

According to some embodiments of the present disclosure, there is provided an electronic device including: a memory configured to store at least one program; a processor configured to execute the at least one program; a display device configured to receive data from the processor and to provide visual information; and a power module configured to supply power to the display device, wherein the display device includes: a substrate including a display area, a peripheral area outside the display area, and a pad area in the peripheral area; a data line in the display area; a fan-out interconnection having one side electrically connected to the data line and another side extending to the pad area; a power interconnection extending in a direction different from that of the fan-out interconnection; and a connecting element at a same layer as the power interconnection and connecting one side of the fan-out interconnection and the data line to each other, wherein the fan-out interconnection includes a protrusion that protrudes in a direction perpendicular to a longitudinal direction of the fan-out interconnection between the connecting element and the power interconnection.

### BRIEF DESCRIPTION OF THE DRAWINGS

The following drawings attached to this specification illustrate preferred embodiments of the present disclosure and, together with the detailed description of the present disclosure described below, serve to further understand the technical idea of the present disclosure; therefore, the present disclosure should not be interpreted as being limited to matters described in such drawings including:

FIG. 1 is a plan view schematically illustrating an example of a display device according to some embodiments of the present disclosure;

FIG. 2 is a perspective view schematically illustrating an example of a bending shape of the display device of FIG. 1, according to some embodiments of the present disclosure;

FIG. 3 is a block diagram schematically illustrating an example of the structure of the display device of FIG. 1, according to some embodiments of the present disclosure;

FIG. 4 is an equivalent circuit diagram of one sub-pixel of the display device of FIG. 1, according to some embodiments of the present disclosure;

FIG. 5 is a cross-sectional view schematically illustrating an example along the line I-I′ of FIG. 1, according to some embodiments of the present disclosure;

FIG. 6 is a schematic enlarged plan view of the part A of FIG. 1, according to some embodiments of the present disclosure;

FIG. 7 is a plan view schematically illustrating an example of the fan-out interconnection, the power interconnection, and the connecting element shown in FIG. 1, according to some embodiments of the present disclosure;

FIG. 8 is a plan view schematically illustrating an example of a residual film formed in the fan-out interconnection shown in FIG. 7, according to some embodiments of the present disclosure;

FIG. 9 is a plan view schematically illustrating another example of the fan-out interconnection, the power interconnection, and the connecting element shown in FIG. 1, according to some embodiments of the present disclosure;

FIG. 10 is a plan view schematically illustrating another example of the fan-out interconnection, the power interconnection, and the connecting element shown in FIG. 1, according to some embodiments of the present disclosure;

FIG. 11 is a plan view schematically illustrating another example of the fan-out interconnection, the power interconnection, and the connecting element shown in FIG. 1, according to some embodiments of the present disclosure;

FIG. 12 is a block diagram of an electronic device according to some embodiments of the present disclosure; and

FIG. 13 shows schematic diagrams of electronic devices according to various embodiments, according to some embodiments of the present disclosure.

### DETAILED DESCRIPTION

The present disclosure may be modified in various suitable ways and has various embodiments. Specific embodiments are illustrated in the drawings and described in detail in the detailed description. The effects and features of the present disclosure and the method for achieving them will become clear with reference to the embodiments described in detail below together with the drawings. However, the present disclosure is not limited to the embodiments disclosed below and may be implemented in various forms.

In the examples below, the terms first, second, etc. are not used in a limiting sense but are used for the purpose of distinguishing one component from another.

In the examples below, singular expressions include plural expressions unless the context clearly indicates otherwise.

In the drawings, the sizes of components may be exaggerated or reduced for convenience of explanation. For example, the size and thickness of each component shown in the drawing are arbitrarily shown for convenience of explanation, and thus the present disclosure is not necessarily limited to what is shown.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

Hereinafter, embodiments of the present disclosure will be described in detail with reference to the attached drawings. When describing with reference to the drawings, identical or corresponding components will be given the same drawing reference numerals.

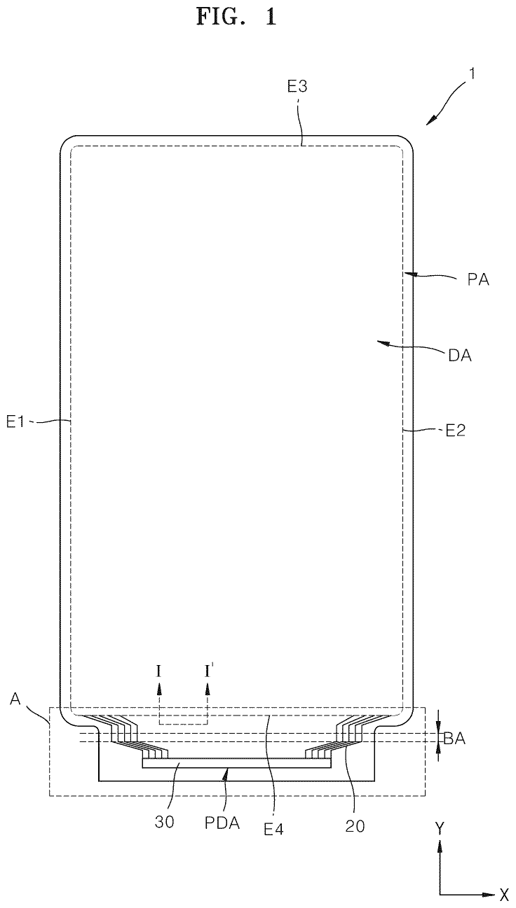

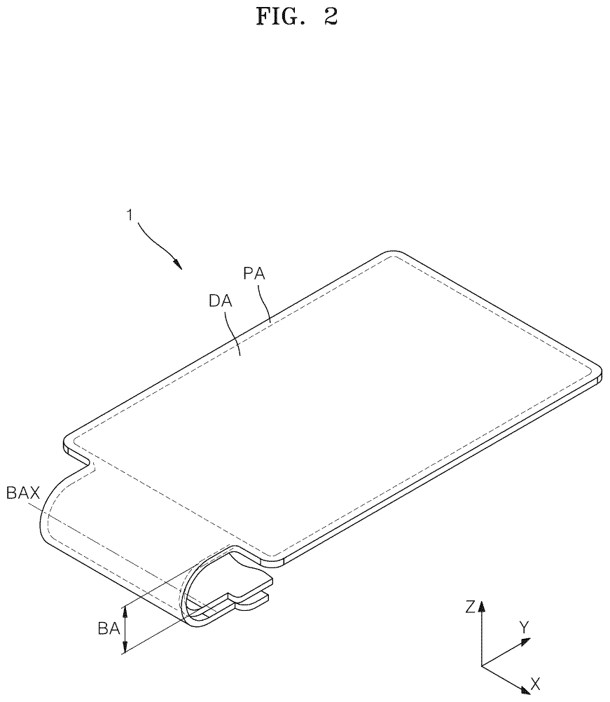

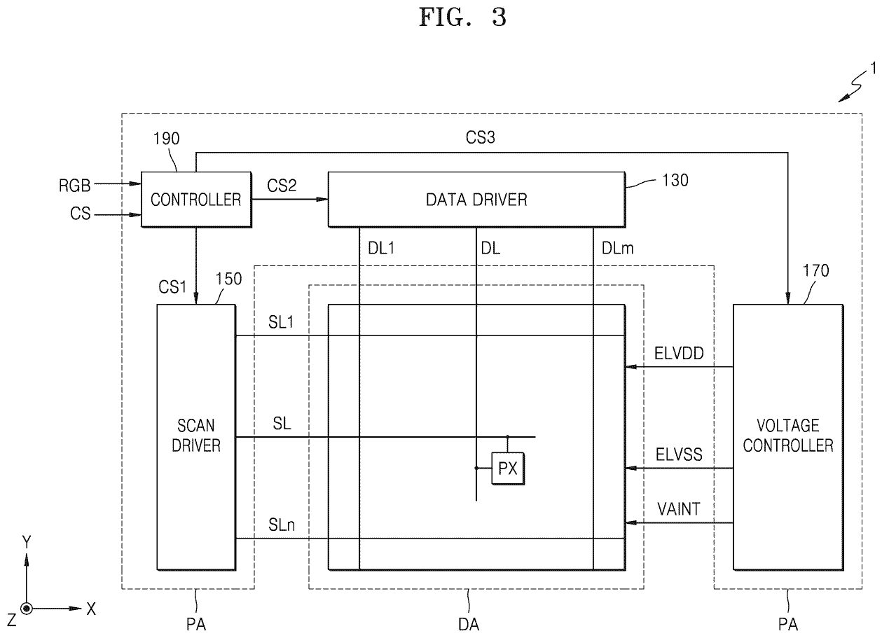

FIG. 1 is a plan view schematically illustrating an example of a display device 1 according to some embodiments of the present disclosure. FIG. 2 is a perspective view schematically illustrating an example of a bending shape of the display device 1 of FIG. 1, according to some embodiments of the present disclosure. FIG. 3 is a block diagram schematically illustrating an example of a structure of the display device 1 of FIG. 1, according to some embodiments of the present disclosure.

Referring to FIGS. 1 to 3, the display device 1 according to some embodiments of the present disclosure includes a display area DA in which a plurality of pixels are positioned, and a peripheral area PA positioned outside the display area DA. The peripheral area PA may be referred to as a non-display area NDA. In some embodiments, the peripheral area PA may include a pad area PDA, which is positioned on one side of the display area DA and in which various electronic components such as integrated circuits (IC) and printed circuit boards are electrically attached, and a bending area BA between the display area DA and the pad area PDA. The display area DA, the peripheral area PA, the pad area PDA, and the bending area BA may be defined on a substrate.

FIG. 1 is a plan view illustrating the shape of a substrate during the manufacturing process of the display device 1, and the substrate may have the bending area BA bent based on a bending axis BAX extending in the first direction (e.g., x-axis direction), as illustrated in FIG. 2. In this regard, the bending direction may be configured such that the pad area PDA is positioned behind the display area DA. Accordingly, the area of the peripheral area PA perceived by the user may be reduced (e.g., minimized).

For this purpose, the substrate may include a transparent glass material with SiO₂ as a main component thereof. However, the material for the substrate is not limited thereto, and a transparent plastic material may instead be used for the substrate. Plastic materials may include polyethersulfone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (TAC), cellulose acetate propionate (CAP), and the like. In some embodiments, the substrate may be a multilayer structure including a base layer including a polymer resin as described above and a barrier layer. A substrate including a polymer resin may have flexible, rollable, and bendable properties.

In the substrate, the width in the first direction (e.g., x-axis direction) of the peripheral area PA including the bending area BA may be smaller than the width in the first direction (e.g., x-axis direction) of the display area DA is located. In some embodiments, corners of the edge of the substrate may be rounded. The shape may also be applied to the display area DA.

For example, when the display area DA has a rectangle or a shape similar to a square, including a first edge E1 and a second edge E2 facing each other and a third edge E3 and a fourth edge E4 facing each other but positioned between the first edge E1 and the second edge E2, the corners of the display area DA may have a rounded shape. In some embodiments, the display area DA may also have a round shape at other portions of the edge.

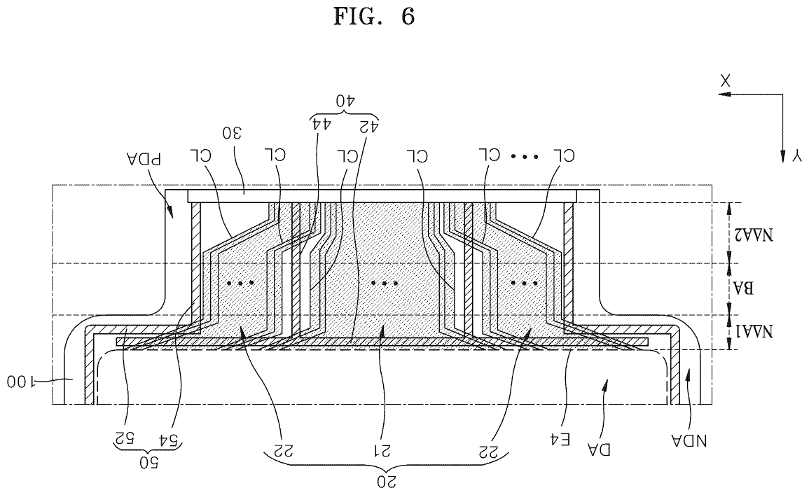

The pad area PDA may be adjacent to the fourth edge E4 among the first edge E1 to the fourth edge E4. A fan-out portion 20 in which conductive lines extend and are arranged may be arranged in the pad area PDA. The conductive lines may cross the bending area BA and have one side electrically connected to the pixel circuit of the display area DA, and another side connected to a driving circuit part 30 including various electronic components such as an integrated circuit IC. This will be further described in detail below in FIG. 6.

Referring to FIG. 3, a plurality of scan lines SL1, . . . , SLn extending along a first direction (e.g., x-axis direction), a plurality of data lines DL1, . . . , DLm extending along a second direction (e.g., y-axis direction) perpendicular to the first direction (e.g., x-axis direction), and a plurality of sub-pixels PX may be positioned in the display area DA. In this regard, m and n may each be a natural number.

The interconnection capable of applying electrical signals to multiple sub-pixels PX may include multiple scan lines SL1, . . . , SLn, multiple data lines DL1, . . . , DLm, etc. The plurality of scan lines SL1, . . . , SLn may be arranged in, for example, a plurality of rows extending in the first direction (e.g., x-axis direction) to transmit scan signals to sub-pixels PX, and a plurality of data lines DL1, . . . , DLm may be arranged in, for example, a plurality of columns extending in the second direction (e.g., y-axis direction) to transmit data signals to the sub-pixels PX, and the plurality of sub-pixels PX may be positioned at intersections of the plurality of scan lines SL1, . . . , SLn and the plurality of data lines DL1, . . . , DLm.

Each sub-pixel PX may include a light-emitting element that may emit red, green, blue, or white light. For example, each sub-pixel PX may include, but is not limited to, an organic light-emitting diode OLED as a light-emitting element.

In the peripheral area PA, a data driver 130 configured to provide data signals to the display area DA, a scan driver 150 configured to provide scan signals to the display area DA, a voltage controller 170 configured to control voltages supplied to the display area DA, and a controller 190 configured to control the data driver 130, the scan driver 150, and the voltage controller 170 may be positioned.

The voltage controller 170 may generate and control a first voltage ELVDD, a second voltage ELVSS, and an initialization voltage VAINT which are provided to the display area DA.

The first voltage ELVDD, the second voltage ELVSS, and the initialization voltage VAINT may be applied to the sub-pixels PX. For example, the first voltage ELVDD may be a positive voltage, and the second voltage ELVSS may be a negative voltage or a ground voltage. That is, the second voltage ELVSS may have a lower level than the first voltage ELVDD.

The controller 190 may receive image signals RGB and a control signal CS from the outside (e.g., a system board). The controller 190 may convert the data format of image signals RGB to match the interface specifications of the data driver 130 and generate image data DATA. The controller 190 may provide image data DATA whose data format has been converted to the data driver 130.

The controller 190 may generate and output a first control signal CS1 and a second control signal CS2 in response to a control signal CS provided from the outside. The first control signal CS1 may be defined as a scan control signal, and the second control signal CS2 may be defined as a data control signal. The first control signal CS1 may be provided to the scan driver 150. The second control signal CS2 may be provided to the data driver 130.

The scan driver 150 may generate a plurality of scan signals in response to the first control signal CS1. A plurality of scan signals may be applied to a plurality of sub-pixels PX via a plurality of scan lines SL1, . . . , SLn.

The data driver 130 may generate a plurality of data voltages corresponding to image data DATA in response to the second control signal CS2. A plurality of data voltages may be applied to a plurality of sub-pixels PX via data lines DL1, . . . , DLm. The data driver 130 may concurrently (e.g., simultaneously) provide data lines DL1, . . . , DLm with the data voltages generated in units of sub-pixel rows to a plurality of sub-pixels PX.

A plurality of sub-pixels PXs may receive a plurality of data voltages in response to a plurality of scan signals. A plurality of sub-pixels PX may display an image by emitting light with a brightness corresponding to a plurality of data voltages. A plurality of sub-pixels PX may display the image by emitting light sequentially or concurrently (e.g., simultaneously).

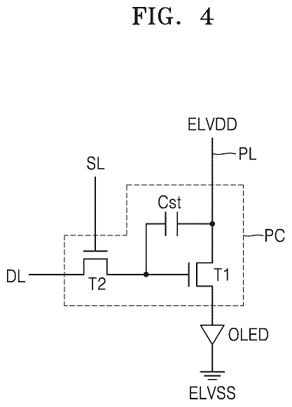

FIG. 4 is an equivalent circuit diagram of one sub-pixel of the display device of FIG. 1, according to some embodiments of the present disclosure.

Referring to FIG. 4, a pixel circuit PC may be connected to a display element, for example an organic light-emitting diode OLED. The pixel circuit PC may include a driving thin film transistor T1, a switching thin film transistor T2, and a storage capacitor Cst. In some embodiments, organic light-emitting diodes OLEDs may emit red, green, or blue light, or may emit red, green, blue, or white light.

The switching thin film transistor T2 may be connected to the scan line SL and the data line DL, and may transmit a data signal or data voltage input through the data line DL to the driving thin film transistor T1 based on a scan signal or switching voltage input through the scan line SL. The storage capacitor Cst may be connected to the switching thin film transistor T2 and the driving voltage line PL, and may store a voltage corresponding to the difference between the voltage received from the switching thin film transistor T2 and the first voltage ELVDD supplied to the driving voltage line PL.

The driving thin film transistor T1 may be connected to the driving voltage line PL and the storage capacitor Cst, and may control the driving current flowing to the organic light-emitting diode OLED from the driving voltage line PL in response to the voltage value stored in the storage capacitor Cst. The organic light-emitting diode OLEDs may emit light with a certain brightness depending on the driving current. A counter electrode (or a common electrode) of the organic light-emitting diode OLED may be supplied with a second voltage ELVSS.

Although FIG. 4 illustrates some embodiments in which the pixel circuit PC includes two thin film transistors and one storage capacitor, the pixel circuit PC may include three, four, five or more thin film transistors.

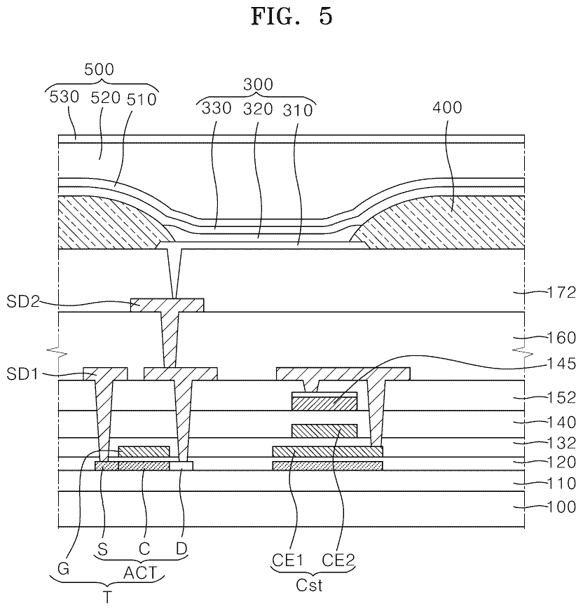

FIG. 5 is a cross-sectional view schematically illustrating an example along the line I-I′ of FIG. 1, according to some embodiments of the present disclosure.

Referring to FIG. 5, a display device according to some embodiments of the present disclosure may include a substrate 100 including a display area, a peripheral area positioned outside the display area, and a pad area positioned in the peripheral area, and a thin film transistor T positioned on the substrate 100. Because the substrate 100 has been described with reference to FIG. 1 and FIG. 2, a description of the substrate 100 may not be repeated herinafter.

In some embodiments, a buffer layer 110 may be formed on the substrate 100. The buffer layer 110 may block impurities during the crystallization process to form polycrystalline silicon, thereby improving (e.g., increasing) the characteristics of the polycrystalline silicon, and provide a flat surface on the substrate 100. The buffer layer 110 may include an inorganic insulating material. For example, the buffer layer 110 may be a single-layer film or multilayer film including at least one of silicon oxynitride (SiON), silicon oxide (SiOx), and silicon nitride (SiNx).

A semiconductor layer ACT covering the buffer layer 110 may be formed. The semiconductor layer ACT may include a source region S, a drain region D, and a channel region C positioned between the source region S and the drain region D.

In some embodiments, the semiconductor layer ACT may include the source region S and the drain region D formed by doping impurities on opposite sides of a channel region C. In this regard, the impurities vary depending on the type of thin film transistor T and may include N-type impurities or P-type impurities. That is, the channel region C, the source region S positioned on one side of the channel region C, and the drain region D positioned on the other side of the channel region C may be called the semiconductor layer ACT.

The source region S or drain region D formed by doping may be interpreted as the source electrode or drain electrode of the thin film transistor T depending on purpose. In some embodiments, the positions of the source region S and drain region D may be swapped depending on the impurities doped into the semiconductor layer ACT.

The semiconductor layer ACT may include polycrystalline silicon. For example, the semiconductor layer ACT may be a layer including low-temperature polycrystalline silicon (LTPS), but is not limited thereto, and the semiconductor layer ACT may instead be a layer including an oxide semiconductor.

A first insulating layer 120 covering the semiconductor layer ACT may be formed. A first conductive layer including a gate electrode G and a lower electrode CE1 of a capacitor Cst may be formed on the first insulating layer 120.

The gate electrode G may form a transistor T together with the semiconductor layer ACT. The transistor T may receive the first voltage ELVDD from the source region S and provide a driving current to a light-emitting element 300. The transistor T may be a driving transistor that is configured to control the current flowing to the light-emitting element 300. In some examples, the transistor T may be a switching transistor that is configured to control the on/off of current.

A second insulating layer 132 may be formed on the first challenging layer to cover it. A second conductive layer including an upper electrode CE2 of the capacitor Cst may be formed on the second insulating layer 132. The upper electrode CE2 of the capacitor Cst may form a capacitor Cst together with the lower electrode CE1 of the capacitor Cst.

The first conductive layer and/or the second conductive layer may include data lines DL to which the data voltages described above in FIG. 3 are applied. Accordingly, the upper electrode CE2 of the capacitor Cst or the lower electrode CE1 of the capacitor Cst may be formed on the same layer as the data line DL.

A third insulating layer 140 may be formed on the second conductive layer to cover the same. A third conductive layer 145 including fan-out interconnections CL, which will be described later, may be formed on the third insulating layer 140. Accordingly, the fan-out interconnection CL may be positioned on a different layer from the data line DL. In some embodiments, the third conductive layer 145 may include electrodes of a capacitor including a program capacitor or a hold capacitor.

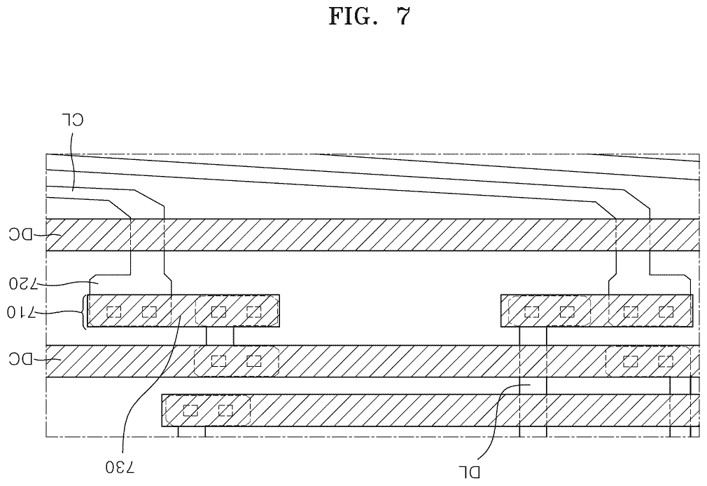

A fourth insulating layer 152 may be formed on the third conductive layer to cover the same. A fourth conductive layer SD1 including a power interconnection DC, which will be described later with reference to FIG. 7, may be formed on the fourth insulating layer 152. Voltages such as the initialization voltage VAINT and the first voltage ELVDD may be applied to the power interconnection DC of the fourth conductive layer SD1.

In some embodiments, the fourth conductive layer SD1 may include a connecting element (730 in FIG. 7) that connects the fan-out interconnection CL and the data line DL to each other. Accordingly, the power interconnection DC may be positioned at the same layer as the connecting element 730.

In some embodiments, the first insulating layer 120 through the fourth insulating layer 152 may each include silicon nitride and/or silicon oxide.

A fifth insulating layer 160 covering the fourth conductive layer SD1 may be formed. A fifth conductive layer SD2 that electrically connects the light-emitting element 300 to the transistor T may be formed on the fifth insulating layer 160.

The first conductive layer to the fifth conductive layers SD2 may each include at least one of aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu).

A sixth insulating layer 172 covering the fifth conductive layer SD2 may be formed. A light-emitting element 300 having a pixel electrode 310, a common electrode 330, and an interlayer 320 arranged between the pixel electrode 310 and the common electrode 330 and including a emission layer may be positioned on the sixth insulating layer 172. The light-emitting element 300 may be, for example, an organic light-emitting element including an organic material.

In some embodiments, the pixel electrode 310 may be an anode of the light-emitting element 300, and the common electrode 330 may be a cathode of the light-emitting element 300. However, the present disclosure is not limited thereto, and depending on the driving method of the display device, the pixel electrode 310 may be the cathode of the light-emitting element 300, and the common electrode 330 may be the anode of the light-emitting element 300. When holes and electrons are injected into the interlayer 320 from the pixel electrode 310 and the common electrode 330, respectively, and the exciton formed by combining the injected holes and electrons drops from the excited state to the ground state, light emission may occur.

The fifth insulating layer 160 and the sixth insulating layer 172 may each include organic materials such as imide polymers, general-purpose polymers such as polymethylmethacrylate (PMMA) or polystyrene (PS), polymer derivatives having phenolic groups, acrylic polymers, aryl ether polymers, amide polymers, fluorine polymers, p-xylene polymers, vinyl alcohol polymers, and blends thereof, or laminated films of organic materials and inorganic materials.

The pixel electrode 310 may be a semitransparent electrode or a reflective electrode. In examples in which the pixel electrode 310 is a semitransparent electrode, the pixel electrode 310 may include, for example, ITO, IZO, ZnO, In₂O₃, IGO or AZO. When the pixel electrode 310 is a reflective electrode, the pixel electrode 310 may have a reflective film including Ag, Mg, Al, Pt, Pd, Au, Ni, Nd, Ir, Cr, and compounds thereof, and a layer including ITO, IZO, ZnO, In₂O₃, IGO, or AZO. The present disclosure is not limited to this embodiment, however, and the pixel electrode 310 may include various materials, and the structure thereof may also be modified in various ways, such as a single-layered structure or a multi-layered structure.

A pixel definition film 400 covering the edge of the pixel electrode 310 may be positioned on the sixth insulating layer 172. The pixel definition film 400 has an opening corresponding to each pixel, that is, an opening that exposes at least a portion of the light-emitting element 300, thereby defining a pixel. In this regard, the opening may be a light-emitting region. In some embodiments, the pixel definition film 400 may prevent arcs or the like from occurring, or substantially reduce instances thereof, between the edge of the pixel electrode 310 and the common electrode 330 by increasing the distance therebetween. The pixel definition film 400 may include an organic material such as polyimide hexamethyldisiloxane (HMDSO), and/or the like.

The interlayer 320 may be formed on the pixel electrode 310 and may be exposed through the opening of the pixel definition film 400. The interlayer 320 may include a low molecular weight material or a high molecular weight material. In examples in which a low-molecular-weight substance is included, a hole injection layer (HIL), a hole transport layer (HTL), an emission layer (EML), an electron transport layer (ETL), and an electron injection layer (EIL) may each have a single or composite laminated structure, and may include various organic substances including copper phthalocyanine (CuPc), N,N-dinaphthalene-1-yl-N,N′-diphenyl-benzidine (NPB), and tris-8-hydroxyquinoline aluminum (Alq3). These layers may be formed by vacuum deposition.

In examples in which the interlayer 320 includes a polymer material, the interlayer 320 may have a structure including an HTL and an EML. In this regard, the HTL may include a conductive polymer (e.g., PEDOT), and the EML may include a polymer material such as a poly-phenylenevinylene (PPV)-based material and a polyfluorene-based material. The structure of the interlayer 320 is not limited to that described above and may have various other structures. For example, the interlayer 320 have a structure that includes either a single layer extending across the plurality of pixel electrodes 310, or individual layers patterned to correspond to each of the plurality of pixel electrodes 310.

The second voltage ELVSS may be applied to the common electrode 330, and the common electrode 330 may be arranged to cover the display area (DA in FIG. 1). That is, the common electrode 330 may be formed integrally to cover a plurality of light-emitting elements 300. The common electrode 330 may be a semitransparent electrode or a reflective electrode. In examples in which the common electrode 330 is a semitransparent electrode, the common electrode 330 may have a layer including a metal having a small work function, such as Li, Ca, LiF/Ca, LiF/Al, Al, Ag, Mg, and compounds thereof, and a semitransparent conductive layer such as ITO, IZO, ZnO, or In₂O₃. In examples in which the common electrode 330 is a reflective electrode, the common electrode 330 may have a layer including Li, Ca, LiF/Ca, LiF/Al, Al, Ag, Mg, and combinations thereof. The composition and material of the common electrode 330 are not limited to these embodiments and various suitable modifications can be applicable.

An encapsulation layer 500 may be positioned on the common electrode 330. The encapsulating layer 500 may protect the light-emitting element 300 from moisture or oxygen from the outside. To this end, the encapsulation layer 500 has such a shape that extends not only to the display area DA where the light-emitting element 300 is located, but also to the peripheral area PA outside the display area DA. This encapsulating layer 500 may include a first inorganic encapsulating layer 510, an organic encapsulating layer 520, and a second inorganic encapsulating layer 530 which are sequentially laminated.

The first inorganic encapsulation layer 510 is formed on the common electrode 330 and may include silicon oxide, silicon nitride, and/or silicon oxynitride. The first inorganic encapsulating layer 510 may be formed being flush with the structure underneath.

The organic encapsulating layer 520 is positioned on the first inorganic encapsulating layer 510 and has a sufficient thickness, so that an upper surface of the organic encapsulating layer 520 may be substantially flat. The organic encapsulating layer 520 may include one or more materials selected from the group consisting of polyethylene terephthalate, polyethylene naphthalate, polycarbonate, polyimide, polyethylene sulfonate, polyoxymethylene, polyarylate, and hexamethyldisiloxane.

The second inorganic encapsulating layer 530 may cover the organic encapsulating layer 520 and may include silicon oxide, silicon nitride, and/or silicon oxynitride. The first inorganic encapsulating layer 510 and the second inorganic encapsulating layer 530 may each have a larger area than the organic encapsulating layer 520 and may contact opposite sides of the organic encapsulating layer 520, respectively. That is, the organic encapsulating layer 520 may be prevented from being exposed to the outside by the first inorganic encapsulating layer 510 and the second inorganic encapsulating layer 530.

As describe above, because the encapsulation layer 500 includes the first inorganic encapsulation layer 510, the organic encapsulation layer 520, and the second inorganic encapsulation layer 530, due to the multilayer structure, even if a crack occurs within the encapsulation layer 500, the crack may be prevented from being connected between the first inorganic encapsulation layer 510 and the organic encapsulation layer 520 or between the organic encapsulation layer 520 and the second inorganic encapsulation layer 530. As a result, it is possible to prevent or substantially reduce (e.g., minimize) the formation of a path through which moisture or oxygen from the outside may penetrate into the display area DA in FIG. 1.

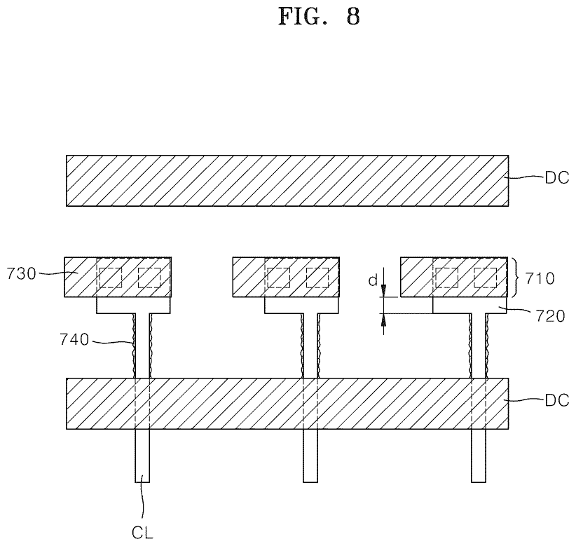

FIG. 6 is a schematic plan view enlarged from the part A of FIG. 1, according to some embodiments of the present disclosure. FIG. 7 is a schematic plan view illustrating an example of fan-out interconnection, the power interconnection, and the connecting element shown in FIG. 1, according to some embodiments of the present disclosure. FIG. 8 is a schematic plan view illustrating another example of fan-out interconnection, the power interconnection, and the connecting element shown in FIG. 1, according to some embodiments of the present disclosure.

Referring to FIGS. 6 to 8 together with FIG. 5, a first voltage line 40, a second voltage line 50, a fan-out portion 20, etc. may be positioned in the non-display area NDA between the display area DA and the pad area PDA of the substrate 100. In this regard, as described in FIG. 1, the non-display area NDA may refer to the peripheral area PA.

The first voltage ELVDD or the initialization voltage VAINT may be applied to the first voltage line 40, and the second voltage ELVSS may be applied to the second voltage line 50. The first voltage line 40 may be connected to the fourth conductive layer SD1 of FIG. 5, and the second voltage line 50 may be connected to the common electrode 330 of FIG. 5 directly or via other interconnections.

The first voltage line 40 may include a power interconnection 42 extending in the first direction (e.g., x-axis direction) on one side of the display area DA, for example, the outer side of the fourth edge E4, and a first connecting portion 44 protruding in the second direction (e.g., y-axis direction) from the power interconnection 42. In this regard, the power interconnection 42 may refer to the same interconnection as the power interconnection DC of FIG. 7. A plurality of first connecting portions 44 may be provided, and may each be connected to the driving circuit part 30 positioned in the pad area PDA across the bending area BA.

The second voltage line 50 may surround edges of the display area DA except for one edge of the display area DA adjacent to the first voltage line 40. The second voltage line 50 may include a main voltage line 52 corresponding to opposite ends of the power interconnection 42 and the remaining areas of the display area DA, and a second connecting portion 54 protruding and extending along the second direction (e.g., y-axis direction) from an end of the main voltage line 52. The second connecting portion 54 may be connected to the driving circuit part 30.

The fan-out portion 20 includes a plurality of fan-out interconnections CL, and the plurality of fan-out interconnections CL are electrically connected to the data line DL to transmit a data signal applied from the driving circuit part 30 to a pixel circuit (PC of FIG. 4).

Hereinafter, for convenience of explanation, as illustrated in FIG. 6, an area of the non-display area NDA of the substrate 100 between the bending area BA and the display area DA is defined as a first non-display area NDA1, and an area positioned on the opposite side of the first non-display area NDA1 with respect to the bending area BA is defined as the second non-display area NDA2. That is, the second non-display area NDA2 is an area that is not visible from the front when the bending area BA is bent, and may be an area between the bending area BA and the driving circuit part 30.

A plurality of fan-out interconnections CL may be arranged to sequentially pass through the first non-display area NDA1, the bending area BA, and the second non-display area NDA2. The length of the pad area PDA may be shorter than one side of the display area DA adjacent to the pad area PDA, and accordingly, the spacings between fan-out interconnections CL may become narrower as moving from the display area DA to the pad area PDA. In some embodiments, the bending area BA is a region where stress is concentrated, and in order to reduce (e.g., minimize) damage to the fan-out interconnections CLs during bending, the fan-out interconnections CLs may extend in a direction parallel to the bending direction in the bending area. Accordingly, the fan-out interconnections CL may be bent in the first non-display area NDA1 and the second non-display area NDA2.

The fan-out portion 20 may be divided into a plurality of regions spaced apart from each other at least in the bending area BA. For example, as illustrated in FIG. 6, the fan-out portion 20 may include two second fan out sections 22 arranged on opposite sides of the first fan out section 21 with respect to the first fan out section 21. However, the present disclosure is not limited thereto, and the fan-out portion 20 may be divided into four or more regions.

According to some embodiments of the present disclosure, the display device may include the data line DL arranged in the display area DA, the fan-out interconnection CL having one side electrically connected to the data line DL and anther end extended to the pad area PDA, the power interconnection DC extending in a direction different from that of the fan-out interconnection CL, and a connecting element 730 positioned at the same layer as the power interconnection DC and connecting the one side of the fan-out interconnection CL to the data line DL.

In some embodiments, the fan-out interconnection CL may include a protrusion 720 that protrudes in a direction different from the longitudinal direction of the fan-out interconnection CL between the connecting element 730 and the power interconnection DC. That is, the fan-out interconnection CL may include a protrusion 720 that protrudes in a direction different from the longitudinal direction of the fan-out interconnection CL outside the connecting element 730 and the overlapping area 710 of the fan-out interconnection CL. In this regard, the protrusion direction of the protrusion 720 may be, for example, perpendicular to or at an acute angle with respect to the longitudinal direction of the fan-out interconnection CL.

The protrusion 720 may be arranged continuously with the overlapping area 710 of the connecting element 730 and the fan-out interconnection CL, and the protrusion 720 may protrude from opposite sides of the fan-out interconnection CL.

As described and illustrated in FIG. 5, the fan-out interconnection CL may be positioned on the data line DL positioned on the substrate 100, and the connecting element 730 electrically connecting the data line DL to the fan-out interconnection CL may be positioned on the fan-out interconnection CL. In some embodiments, the connecting element 730 may be positioned at the same layer as the power interconnection DC to which the first voltage ELVDD or the initialization voltage VAINT is applied.

Accordingly, during the manufacturing process of the display device, the fourth conductive layer SD1 including the power interconnection DC and the connecting element 730 may be patterned on the third conductive layer 145 including the fan-out interconnection CL. When patterning the fourth conductive layer SD1, between the connecting element 730 and the power interconnection DC which are positioned at the same layer and adjacent to each other, a residual film 740 of the fourth conductive layer SD1 that has not been etched away may remain on opposite sides of the fan-out interconnection CL along the longitudinal direction of the fan-out interconnection CL due to a step of the fan-out interconnection CL arranged under the connecting element 730 and the power interconnection DC. As a result, a path for current to flow between the adjacent connecting element 730 and the power interconnection DC is created due to the residual film 740, so that the adjacent connecting element 730 and the power interconnection DC may be short-circuited, thereby reducing the stability of the display device.

However, as in some embodiments of the present disclosure, in examples in which the fan-out interconnection CL includes the protrusion 720 protruding in a direction different from the longitudinal direction of the fan-out interconnection CL between the connecting element 730 and the power interconnection DC, because the residual film 740 remains on opposite sides of the fan-out interconnection CL along the longitudinal direction of the fan-out interconnection CL, even if the residual film 740 that has not been etched away remains between the power interconnection DC and the connecting element 730, the residual film 740 does not form a current path connecting the power interconnection DC to the connecting element 730, which are adjacent to each other. This prevents the power interconnection DC and the connecting element 730 from being short-circuited with each other, thereby improving (e.g., increasing) the stability of the display device and the electronic device including the same.

In FIG. 8, the residual film 740 is depicted as being formed on opposite sides of the fan-out interconnection CL other than the protrusion 720, but the residual film 740 may be formed on opposite sides of the protrusion 720, and the residual film 740 may not remain on the side of the fan-out interconnection CL.

As described above, even if the residual film 740 is formed on opposite sides of the protrusion 720, the residual film 740 formed on opposite sides of the protrusion 720 and the residual film 740 formed on opposite sides of the fan-out interconnection CL other than the protrusion 720 are not connected to each other, so that the power interconnection DC and the connecting element 730 which are adjacent to each other, may not be short-circuited with each other.

In some examples, the width d of the protrusion 720 along the longitudinal direction of the fan-out interconnection CL may be 3 μm to 10 μm. If the width d of the protrusion 720 along the longitudinal direction of the fan-out interconnection CL is less than 3 μm, even if the connecting element 730 and the power interconnection DC are designed not to be electrically connected through the residual films 740 formed on the fan-out interconnection CL, because the width d of the protrusion 720 is short, the residual films 740 formed on opposite sides of the fan-out interconnection CL other than the protrusion 720 may be likely to be connected, causing the power interconnection DC and the connecting element 730 to be short-circuited with each other.

If the width d of the protrusion 720 along the longitudinal direction of the fan-out interconnection CL exceeds 10 μm, when the integration of the display device increases, the power interconnection DC and the connecting element 730, which are adjacent to each other, may be short-circuited with each other through the residual film 740 formed on opposite sides of the protrusion 720.

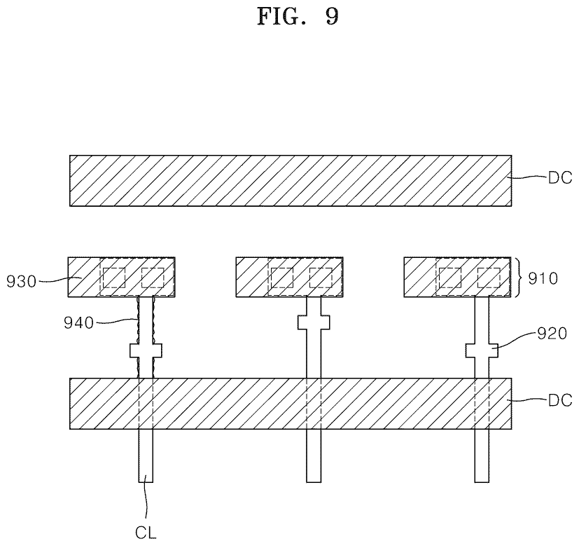

FIG. 9 is a plan view schematically illustrating another example of the fan-out interconnection, the power interconnection, and the connecting element of FIG. 1, according to some embodiments of the present disclosure.

Referring to FIG. 9 together with FIG. 7, according to some other embodiments of the present disclosure, a display device may include the data line DL arranged in the display area DA, the fan-out interconnection CL having one side electrically connected to the data line DL and another side extending to the pad area PDA, the power interconnection DC extending in a direction different from that of the fan-out interconnection CL, and a connecting element 930 positioned at the same layer as the power interconnection DC and connecting the one side of the fan-out interconnection CL to the data line DL.

In some embodiments, the fan-out interconnection CL may include a protrusion 920 that protrudes in a direction different from the longitudinal direction of the fan-out interconnection CL between the connecting element 930 and the power interconnection DC. In this regard, the protrusion 920 may be spaced apart from the connecting element 930 and an overlapping area 910 of the fan-out interconnection CL, and the protrusion direction of the protrusion 920 may be, for example, perpendicular to the longitudinal direction of the fan-out interconnection CL.

During the manufacturing process of the display device, between the connecting element 930 and the power interconnection DC which are positioned at the same layer, a residual film 940 that has not been etched away may remain on opposite sides of the fan-out interconnection CL along the longitudinal direction of the fan-out interconnection CL due to a step of the fan-out interconnection CL arranged under the connecting element 930 and the power interconnection DC.

Because the residual film 940 remains on opposite sides of the fan-out interconnection CL along the length of the fan-out interconnection CL, even if the protrusion 920 extends between adjacent fan-out interconnections CL, there may be a free space where the protrusion 920 does not come into contact with the adjacent fan-out interconnection CL.

Accordingly, in examples in which the protrusion 920 is formed spaced apart from the connecting element 930 and the overlapping area 910 of the fan-out interconnection CL, the protrusion 920 positioned on one fan-out interconnection CL may protrude into the free space to the extent that the protrusion 920 does not come into contact with either another adjacent fan-out interconnection CL or the protrusion 920 of the other adjacent fan-out interconnection CL. In this regard, the protrusion 920 of one fan-out interconnection CL may arranged to be alternately staggered with respect to the protrusion 920 of another adjacent fan-out interconnection CL.

As a result, even if a tolerance occurs during the patterning process of the third conductive layer (e.g., 145 in FIG. 5) including a fan-out interconnection, adjacent fan-out interconnections CL may not come into contact and be short-circuited due to the free space. That is, when the protrusion 920 is spaced apart from the connecting element 930 and the overlapping area 910 of the fan-out interconnection CL, and the protrusions 920 of adjacent fan-out interconnections CL are arranged so as to be staggered with respect to each other, the degree of freedom of the patterning process of the third conductive layer (e.g., 145 of FIG. 5) may be increased by securing the free space during patterning of the third conductive layer (e.g., 145 of FIG. 5).

In FIG. 9, the residual film 940 is depicted as being formed only on the leftmost fan-out interconnection CL, but the residual film 940 may also be formed on opposite sides of a plurality of fan-out interconnections CL and the protrusion 920.

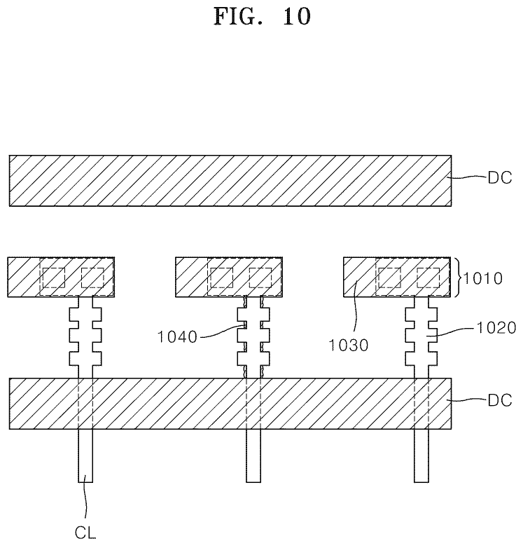

FIG. 10 is a plan view schematically illustrating another example of the fan-out interconnection, the power interconnection, and the connecting element of FIG. 1, according to some embodiments of the present disclosure.

Referring to FIG. 10 together with FIG. 7, according to some other embodiments of the present disclosure, a display device may include the data line DL arranged in the display area DA, the fan-out interconnection CL having one side electrically connected to the data line DL and another side extending to the pad area PDA, the power interconnection DC extending in a direction different from that of the fan-out interconnection CL, and a connecting element 1030 positioned at the same layer as the power interconnection DC and connecting the one side of the fan-out interconnection CL to the data line DL.

The fan-out interconnection CL may include a protrusion 1020 that protrudes in a direction different from the longitudinal direction of the fan-out interconnection CL between the connecting element 1030 and the power interconnection DC. In this regard, the protrusion 1020 may be spaced apart from the connecting element 1030 and the overlapping area 1010 of the fan-out interconnection CL, and the protrusion direction of the protrusion 1020 may be, for example, perpendicular to the longitudinal direction of the fan-out interconnection CL. In some embodiments, the protrusion 1020 of the fan-out interconnection CL may be provided in the form of a plurality of protrusions, and the plurality of protrusions 1020 may be spaced apart from each other along the longitudinal direction of the fan-out interconnection CL.

In examples in which the fan-out interconnection CL includes a plurality of protrusions 1020 spaced apart from each other, because the residual film 1040 remains on opposite sides of the fan-out interconnection CL along the longitudinal direction of the fan-out interconnection CL, even if residual films 1040 that have not been etched away remain between the power interconnection DC and the connecting element 1030, the residual films 1040 do not form a current path connecting the power interconnection DC and the connecting element 1030, which are adjacent to each other, thereby preventing the power interconnection DC and the connecting element 1030, which are adjacent to each other, from being short-circuited with each other, thereby improving (e.g., increasing) the stability of the display device and an electronic device including the same.

In FIG. 10, the residual film 1040 is depicted as being formed only on the central fan-out interconnection CL, but the residual film 1040 may also be formed on opposite sides of a plurality of fan-out interconnections CL and the protrusion 1020.

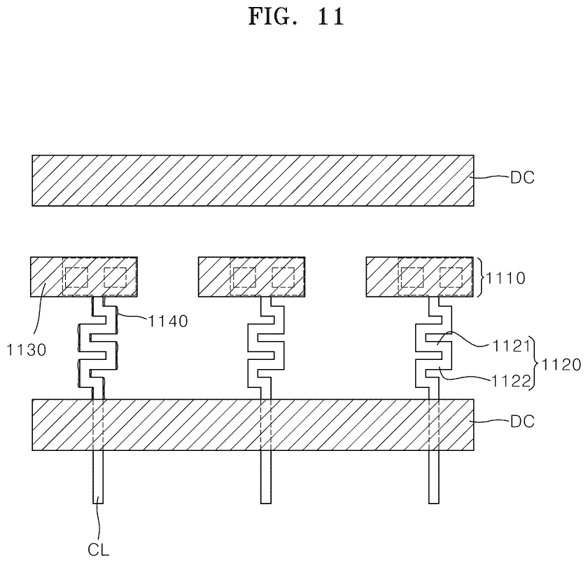

FIG. 11 is a plan view schematically illustrating another example of the fan-out interconnection, the power interconnection, and the connecting element of FIG. 1, according to some embodiments of the present disclosure.

Referring to FIG. 11 together with FIG. 7, according to some other embodiments of the present disclosure, a display device may include the data line DL arranged in the display area DA, the fan-out interconnection CL having one side electrically connected to the data line DL and another side extending to the pad area PDA, the power interconnection DC extending in a direction different from that of the fan-out interconnection CL, and a connecting element 1130 positioned at the same layer as the power interconnection DC and connecting the one side of the fan-out interconnection CL and the data line DL.

The fan-out interconnection CL may include a protrusion 1120 that protrudes in a direction different from the longitudinal direction of the fan-out interconnection CL between the connecting element 1130 and the power interconnection DC. The protrusion direction of the protrusion 1120 may be, for example, perpendicular to the longitudinal direction of the fan-out interconnection CL. In some embodiments, the protrusion 1120 of the fan-out interconnection CL may be provided in the form of a plurality of protrusions, and the protrusions 1120 may include at least one first protrusion 1121 and at least one second protrusion 1122 extending in opposite directions. That is, the fan-out interconnection CL may include a zigzag pattern between the connecting element 1130 and the power interconnection DC.

In examples in which the fan-out interconnection CL includes a zigzag pattern between the connecting element 1130 and the power interconnection DC, because the residual film 1140 remains on opposite sides of the fan-out interconnection CL along the longitudinal direction of the fan-out interconnection CL, even if residual films 1140 that have not been etched away remain between the power interconnection DC and the connecting element 1130, the residual films 1140 do not form a current path connecting the power interconnection DC and the connecting element 1130, which are adjacent to each other, thereby preventing the power interconnection DC and the connecting element 1130 from being short-circuited with each other, thereby improving (e.g., increasing) the stability of the display device and an electronic device including the same.

In FIG. 11, the residual film 1140 is depicted as being formed only on the leftmost fan-out interconnection CL, but the residual film 1140 may also be formed on opposite sides of a plurality of fan-out interconnections CL and the protrusion 1120.

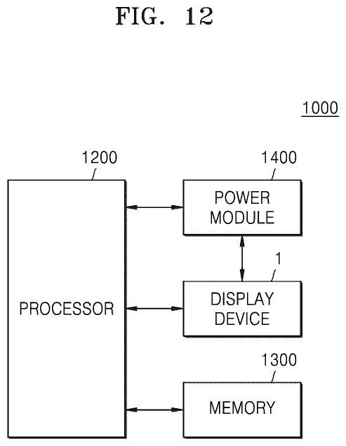

FIG. 12 is a block diagram of an electronic device 1000 according to some embodiments of the present disclosure.

Referring to FIG. 12, the electronic device 1000 according to some embodiments may include the display device 1, a processor 1200, a memory 1300, and a power module 1400.

The display device 1 may receive data from the processor 1200 and provide visual information. The display device 1 may be the display device 1 according to some embodiments of the present disclosure described above.

The processor 1200 may include at least one of a central processing unit (CPU), an application processor (AP), a graphic processing unit (GPU), a communication processor (CP), an image signal processor (ISP), and a controller. For example, the processor 1200 may operate by executing at least one program.

The memory 1300 may store data information used for the operation of the processor 1200 or the display device 1. For example, the memory 1300 may store the at least one programs. When the processor 1200 executes an application stored in the memory 1300, an image data signal and/or an input control signal is transmitted to the display device 1, and the display device 1 may process received signals and output image information through a display screen.

The power module 1400 may include a power supply module, such as a power adapter or a battery device, and a power conversion module that converts power supplied by the power supply module to generate power utilized for the operation of the electronic device 1000. For example, the power module 1400 may supply power to the display device 1.

At least one of the components of the electronic device 1000 may be included in the display device 1 according to some embodiments. In some embodiments, some of the individual modules that are functionally included within one module may be included within the display device 1 and others may be provided separately from the display device 1.

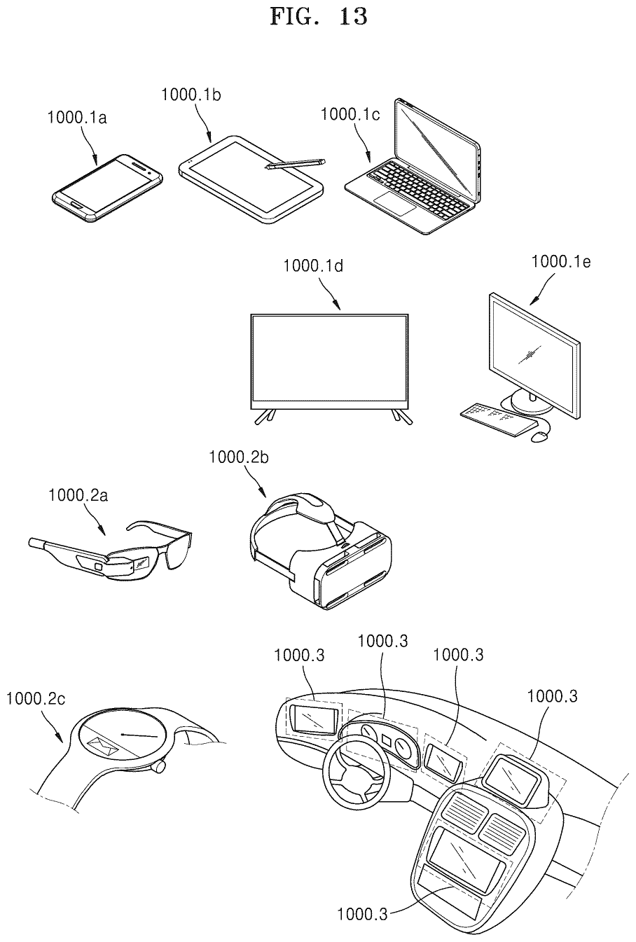

FIG. 13 is a schematic diagram of an electronic device according to some embodiments of the present disclosure.

Referring to FIG. 13, various electronic devices to which the display device according to some embodiments of the present disclosure is applied may include not only image display electronic devices such as a smartphone 1000.1a, a tablet PC 1000.1b, a laptop 1000.1c, a TV 1000.1d, and a desktop monitor 1000.1e, but also wearable electronic devices including display devices such as smart glasses 1000.2a, a head mounted display 1000.2b, and a smart watch 1000.2c, and vehicle electronic devices 1000.3 including display devices such as a center information display (CID) disposed on an automobile's instrument panel, center fascia, dashboard, and a room mirror display.

According to some embodiments of the present disclosure, because a fan-out interconnection disposed under a power interconnection and a connecting element includes a protrusion that protrudes in a direction perpendicular to the longitudinal direction of the fan-out interconnection between the connecting element and the power interconnection, even if unetched residual films remain between the power interconnection and the connecting element, the residual films do not form a current path connecting the power interconnection and the connecting element, which are adjacent to each other, thereby preventing the power interconnection and the connecting element, which are adjacent to each other, from being short-circuited with each other. Thus, the stability of a display device and an electronic device including the same may be improved (e.g., increased).

However, the effects obtainable through the present disclosure are not limited to the effects described above, and other technical effects not described will be clearly understood by those skilled in the art from the description of the present disclosure described below.

Although the present disclosure has been described above by means of limited embodiments and drawings, the present disclosure is not limited thereto, and it is obvious that various modifications and variations are possible within the scope of the technical idea of the present disclosure and the equivalent scope of the patent claims to be described below by a person skilled in the art to which the present disclosure pertains.

What is claimed is:

1. A display device comprising:
a substrate comprising a display area, a peripheral area outside the display area, and a pad area in the peripheral area;
a data line in the display area;
a fan-out interconnection having one side electrically connected to the data line and another side extending to the pad area;
a power interconnection extending in a direction different from that of the fan-out interconnection; and
a connecting element positioned at a same layer as the power interconnection and connecting the one side of the fan-out interconnection to the data line,
wherein the fan-out interconnection comprises a protrusion that protrudes in a direction perpendicular to a longitudinal direction of the fan-out interconnection between the connecting element and the power interconnection.

2. The display device of claim 1, wherein the protrusion is arranged continuously with an overlapping area of the connecting element and the fan-out interconnection.

3. The display device of claim 2, wherein a width of the protrusion along the longitudinal direction of the fan-out interconnection is 3 μm to 10 μm.

4. The display device of claim 1, wherein the protrusion protrudes from opposite sides of the fan-out interconnection.

5. The display device of claim 1, wherein the protrusion is offset from an overlapping area of the connecting element and the fan-out interconnection.

6. The display device of claim 5, wherein the protrusion of the fan-out interconnection comprises a plurality of protrusions, and the plurality of protrusions are offset from each other along the longitudinal direction of the fan-out interconnection.

7. The display device of claim 1, wherein the protrusion of the fan-out interconnection comprises a plurality of protrusions, and the protrusions comprise at least one first protrusion and at least one second protrusion extending in opposite directions.

8. The display device of claim 7, wherein the fan-out interconnection comprises a zigzag pattern between the connecting element and the power interconnection.

9. The display device of claim 1, wherein one end of the fan-out interconnection is electrically connected to a driving circuit part.

10. The display device of claim 1, wherein the fan-out interconnection extends in a direction parallel to a bending direction in a bending region.

11. A display device comprising:
a substrate comprising a display area, a peripheral area outside the display area, and a pad area in the peripheral area;
a thin film transistor on the substrate;
a light-emitting element electrically connected to the thin film transistor;
a data line through which a data signal is applied to the thin film transistor;
a fan-out interconnection having one side electrically connected to the data line and another side extending to the pad area; and
a connecting element for connecting the one side of the fan-out interconnection to the data line,
wherein the fan-out interconnection comprises a protrusion that protrudes in a direction perpendicular to a longitudinal direction of the fan-out interconnection outside an overlapping area of the connecting element and the fan-out interconnection.

12. The display device of claim 11, further comprising:
an upper electrode of a capacitor or a lower electrode of the capacitor formed in a same layer as the data line.

13. The display device of claim 11, wherein the data line and the fan-out interconnection are at different layers.

14. The display device of claim 11, further comprising:
a power interconnection extending in a direction different from that of the fan-out interconnection,
wherein the power interconnection is positioned at a same layer as the connecting element.

15. The display device of claim 14, wherein the protrusion is between the connecting element and the power interconnection.

16. The display device of claim 11, wherein the protrusion is arranged continuously with an overlapping area of the connecting element and the fan-out interconnection.

17. The display device of claim 11, wherein the protrusion is offset from an overlapping area of the connecting element and the fan-out interconnection.

18. The display device of claim 17, wherein the protrusion of the fan-out interconnection comprises a plurality of protrusions, and the plurality of protrusions are offset from each other along the longitudinal direction of the fan-out interconnection.

19. The display device of claim 11, wherein the fan-out interconnection comprises a plurality of fan-out interconnections and the protrusion comprises a plurality of protrusions, and a protrusion of one of the fan-out interconnections is arranged to be alternately staggered with respect to a protrusion of another one of the fan-out interconnections which is adjacent to the one of the fan-out interconnections.

20. An electronic device comprising:
a memory configured to store at least one program;
a processor configured to execute the at least one program;
a display device configured to receive data from the processor and to provide visual information; and
a power module configured to supply power to the display device,
wherein the display device comprises:
a substrate comprising a display area, a peripheral area outside the display area, and a pad area in the peripheral area;
a data line in the display area;
a fan-out interconnection having one side electrically connected to the data line and another side extending to the pad area;
a power interconnection extending in a direction different from that of the fan-out interconnection; and
a connecting element at a same layer as the power interconnection and connecting one side of the fan-out interconnection and the data line to each other,
wherein the fan-out interconnection comprises a protrusion that protrudes in a direction perpendicular to a longitudinal direction of the fan-out interconnection between the connecting element and the power interconnection.
